(19) United States
(12) Patent Application Publication
(10) Pub. No.: US 2011/0141682 A1
(43) Pub. Date: Jun. 16, 2011

(54) External hard disk drive case

(76) Inventor: Wen-Ping Chen, Taipei City (TW)

(21) Appl. No.: 12/654,180

(22) Filed: Dec. 14, 2009

(51) Int. Cl. H05K 7/00

(52) U.S. Cl. 361/679.33

(57) ABSTRACT

An external hard disk drive case comprises a first housing, a trim ring, a second housing and a circuit board. The trim ring is made of a light-transmitting material and sandwiched between the first housing and the second housing. The circuit board is disposed within the first housing. The circuit board is provided thereon with a light-emitting component in the socket of which is disposed a light guiding strip that is peripherally disposed within the trim ring. When used, the light emitted by a luminous source of the light-emitting component disposed in the socket can lighten the light guiding strip peripherally disposed within the trim ring so as to produce a peripheral luminous effect which considerably improves the identifiable and aesthetic properties in use.

### BACKGROUND OF THE INVENTION

1. Field of the Invention

The present invention relates to an external hard disk drive case, and more particularly to an external hard disk drive case structure which has a peripheral luminous effect when in use.

2. Related Art

As computer science and technology change with each passing day, capacities for storing various computer multimedia data, such as music, images, films, or the like, also significantly increase. These data are exchanged via various carriers, such as CD discs, DVD discs, or hard disk drives, etc. Among them, the capacity of a hard disk drive is high, and it can be read and written repeatedly, and has a high read/write speed, a low unit usage cost and good protectiveness. No doubt it is possible to regard a hard disk drive as an optimal carrier. A dedicated external case for a hard disk drive is used to envelop and electrically and signally connect a hard disk drive to a computer device (such as a personal or notebook computer) for data exchange.

Referring to FIG. 1, there is a schematic view showing a structure of an external hard disk drive case of the prior art. As shown in the figure, the external hard disk drive case 10 includes an upper cover 11, a lower cover 12 that are made of a material, such as an aluminum alloy, aluminum magnesium alloy, rigid plastics, or the like, and a circuit board 13 enveloped between the upper cover 11 and the lower cover 12. The circuit board 13 further includes an internal connection port 131, an external connection port 132 and a plurality of indicator lamps 133. The external connection port 132 and the indicator lamps 133 pass through out of one of the upper cover 11 and the lower cover 12. The internal connection port 131 is selected from an integrated drive electronics (IDE) interface and a serial advanced technology attachment (SATA) interface. The external connection port 132 is one selected from a universal serial bus (USB) interface, a serial advanced technology attachment (SATA) interface and a fire wire (IEEE1394) interface. When a hard disk drive 20 is disposed within the external hard disk drive case 10, the hard disk drive is electrically and signally connected to the circuit board 13 through the internal connection port 131. Then, the circuit board 13 is electrically and signally connected to the computer device through a power signal line so that the indicator lamps emit different light colors to improve the identifiable and aesthetic properties in use.

However, the indicator lamps 133 used in the external hard disk drive case 10 mostly belong to the single-point or multipoint light emitting type. Colors can be changed or multiple colors can be displayed simultaneously to produce indicating effects of various service conditions, but in practical use, the identifiability will be readily influenced because the indicator lamps 133 are shielded by other articles due to their arrangement angles. Furthermore, consumers put relatively strong emphasis on the appearance of products themselves today. Hence, it is indeed difficult for such external hard disk drive case 10 of unexciting shapes or structures to meet the requirements of the objective consumer market. There is strong demand for a new type of external hard disk drive case.

Therefore, an external hard disk drive case structure is designed according to the present invention, which combines a luminous source having an indicating effect with sockets and a light guiding strip to produce a peripheral luminous effect through a light-transmitting trim ring disposed on the periphery of the housings, so as to improve the identifiable and aesthetic properties when the external hard disk drive case is in use.

### SUMMARY OF THE INVENTION

An object of the present invention aims to provide an external hard disk drive case structure with a peripheral luminous effect, so as to improve the identifiable and aesthetic properties in use.

Another object of the present invention aims to offer an engagement structure of an external hard disk drive case, so as to enhance the convenience in assembly of a hard disk drive.

To achieve the foregoing object, an external hard disk drive case of the present invention, which is provided for assembling a hard disk drive therein to serve as an external storage medium, comprises: a first housing, which is provided with a plurality of snap-fitting portions extending inwardly on the periphery of the first housing, and a plurality of first fixed portions being provided between the snap-fitting portions and the inner wall surface of the first housing; a trim ring, which is made of a light-transmitting material and with a shape corresponding to the first housing, the trim ring being provided with a plurality of second fixed portions corresponding to the first fixed portions, the second fixed portions and the first fixed portions of the first housing being joined to form one piece, a peripheral groove being formed between the trim ring and the snap-fitting portions of the first housing; a second housing, which is provided with a plurality of hooks disposed on the surface of the second housing corresponding to the first housing, and the hooks engaging with the snap-fitting portions of the first housing; and a circuit board, which is disposed within the first housing and includes a light-emitting component having: at least one socket, which is provided with a luminous source disposed at the inner side of the socket, and is provided with an insertion hole at one end of the socket; and a light guiding strip, which is inserted into the insertion hole of the socket at one end of the light guiding strip and is peripherally disposed within the peripheral groove. When the case is connected to a computer device in use, the computer device supplies power to the circuit board so that the luminous source is actuated and then lightened. The light is guided into the light guiding strip to have an effect of lightening the whole strip. The light guiding strip, which is located with respect to the light-transmitting trim ring, is used to produce a peripheral luminous effect for the external hard disk drive case, thus improving the identifiable and aesthetic properties in use. Furthermore, the first housing and the second housing can engage with each other by aligning and slidably inserting the hooks into the correspondingly arranged snap-fitting portions, so as to enhance the convenience in assembly.

Furthermore, in another embodiment, the circuit board is provided with two sockets. The two ends of the light guiding strip are respectively inserted into the two sockets to increase the brightness in use or to make the brightness more uniform. The circuit board further includes an external connection port. The first housing further includes a through hole corresponding to the external connection port so that the external connection port passes through out of and is disposed within the through hole to allow the external connection port to be electrically and signally connected to the computer device by a power signal line. Moreover, the circuit board includes an internal connection port and the internal connection port is electrically and signally connected to the hard disk drive.

### BRIEF DESCRIPTION OF THE DRAWINGS

FIG. 1 is a schematic view showing a structure of an external hard disk drive case of the prior art.

FIG. 2 is a three-dimensional exploded view showing a preferred embodiment according to the present invention.

FIG. 3 is a three-dimensional appearance view showing a preferred embodiment according to the present invention after assembled.

FIG. 4 is a sectional view (I) showing a preferred embodiment according to the present invention after assembled.

FIG. 5 is a sectional view (II) showing a preferred embodiment according to the present invention after assembled.

FIG. 6 is a schematic view showing a state of a preferred embodiment according to the present invention when in use.

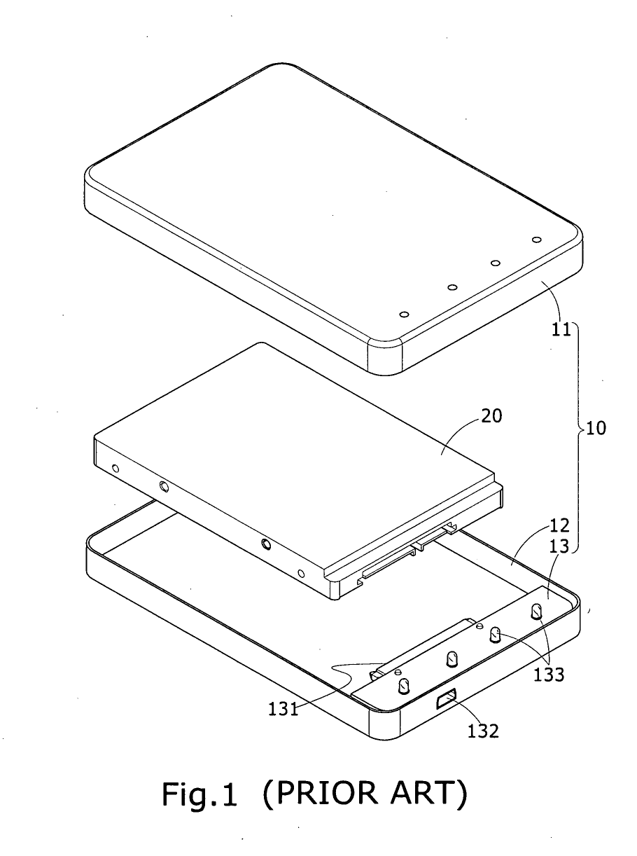

### DETAILED DESCRIPTION OF THE PREFERRED EMBODIMENTS

The contents of the present invention will become more apparent from the following description when taken in conjunction with the drawings.

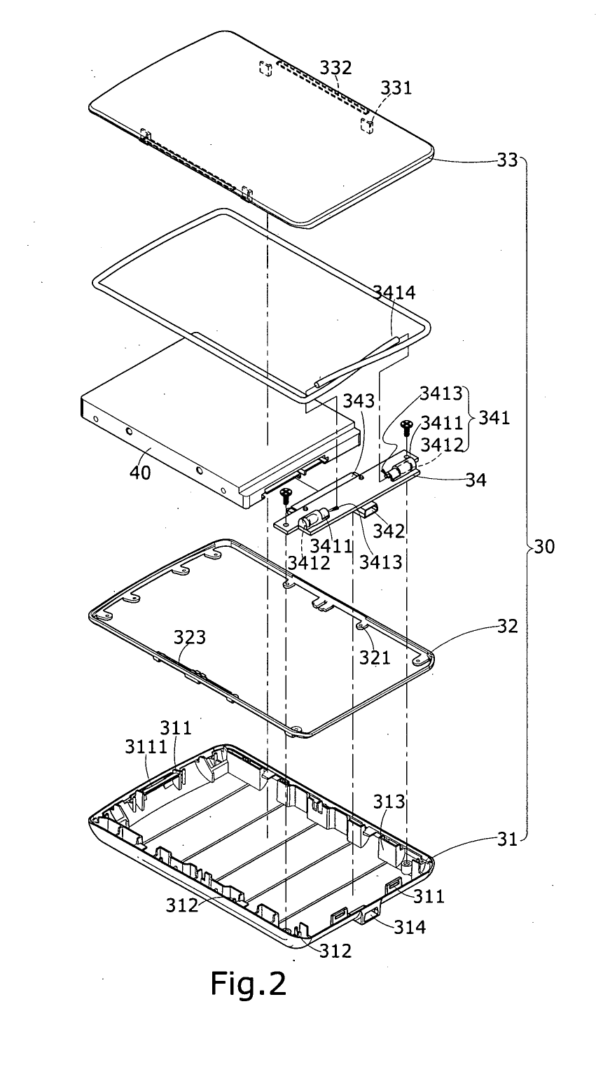

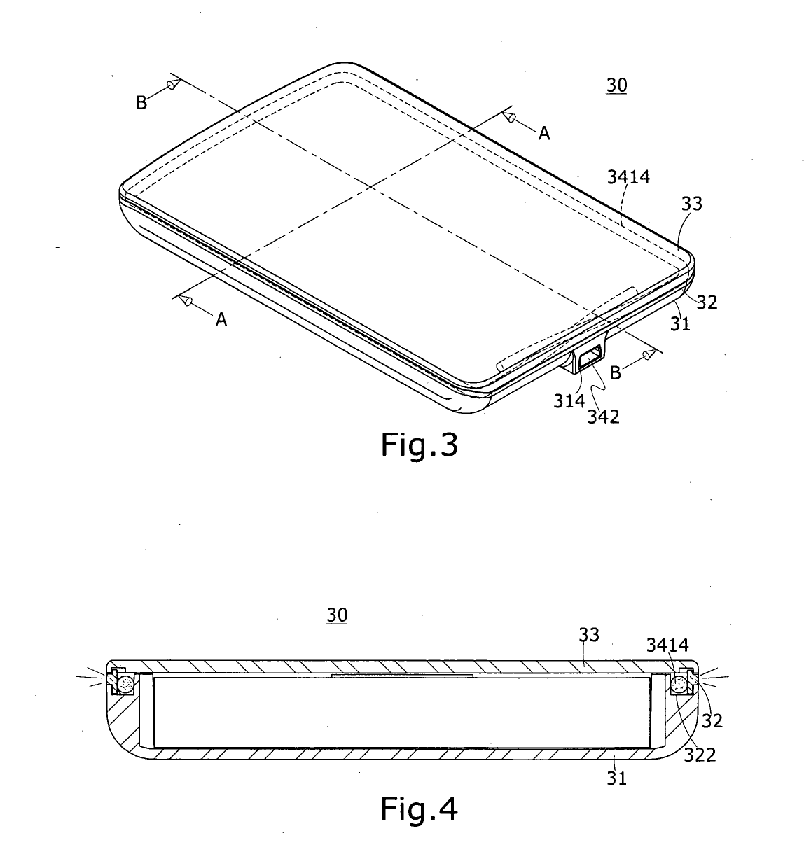

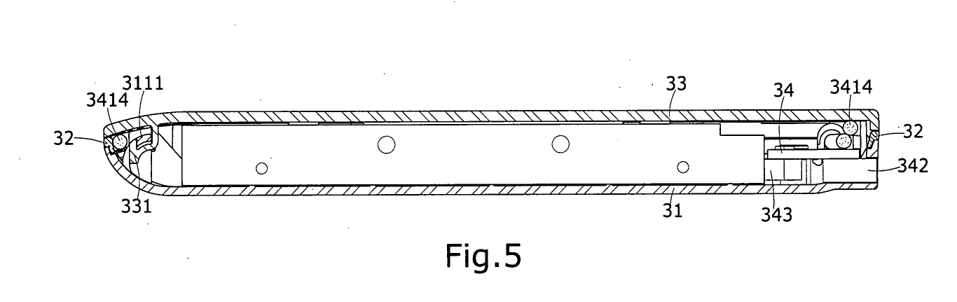

Referring to FIGS. 2 to 5, there are shown a three-dimensional exploded view showing a preferred embodiment according to the present invention, a three-dimensional appearance view showing a preferred embodiment according to the present invention after assembled, and sectional views showing a preferred embodiment according to the present invention after assembled in different directions. As shown, an external hard disk drive case 30 of the present invention, which is provided for assembling a common hard disk drive 40 (for example, a 1.8″, 2.5″ or 3.5″ hard disk drive, etc., shown in the figure is a 2.5″ hard disk drive, but the present invention is not limited thereto) therein to serve as an external storage medium. The external hard disk drive case 30 comprises a first housing 31, a trim ring 32, a second housing 33 and a circuit board 34.

The first housing 31 is provided with a plurality of snap-fitting portions 311 extending inwardly on the periphery of the first housing 31: A plurality of first fixed portions 312 are provided between the snap-fitting portions 311 and the inner wall surface of the first housing 31 (as shown in FIG. 2, the first fixed portions 312 are vertically upward convex pillars). As shown in the figure, the snap-fitting portions 311 are provided respectively on two sides of the first housing 31. The first housing 31 includes bulkheads 313 on one side of the first housing 31 and the bulkheads 31 are perpendicular to the inner surface of the first housing 31. The rear snap-fitting portion 311 further has a first inclined surface 3111 which is inclined downwardly.

The trim ring 32 is made of a light-transmitting material and with a shape corresponding to the first housing 31. The trim ring 32 is provided with a plurality of second fixed portions 321 corresponding to the first fixed portions 312 (as shown in FIG. 2, the second fixed portions 321 are a plurality of inwardly extending tongues, each of which is provided with a through hole corresponding to the above-mentioned pillar). The second fixed portions 321 and the first fixed portions 312 of the first housing 31 are joined to form one piece (after the pillars pass through out of the through holes, the ends of the pillars are heated and trimmed). A peripheral groove 322 is formed between the trim ring 32, the snap-fitting portions 311 of the first housing 31 and the bulkheads 313. Furthermore, the trim ring 32 includes first positioning portions 323 respectively on the upper edges of its two sides (as shown in FIG. 2, the first positioning portions 323 are in a rib form).

The second housing 33 is provided with a plurality of hooks 331 disposed on the surface of the second housing 33 corresponding to the first housing 31, and the hooks 331 engage with the snap-fitting portions 311 of the first housing 31, so that the first housing 31 and the second housing 33 are closed to each other completely to form a closed containing space. Also, the second housing 33 includes second positioning portions 332 corresponding to the first positioning portions 323 (as shown in FIG. 2, the second positioning portions are in a recess form). The first positioning portions 323 engage with the second positioning portions 332 after the second housing 33 is joined with the trim ring 32, so as to increase the fixing effect after joined together.

The circuit board 34 is disposed within the containing space formed by the joined first housing 31 and second housing 33. The circuit board 34 includes a light-emitting component 341 having: two correspondingly arranged sockets 3411, each of which is provided with a luminous source 3412 disposed at the inner side of the socket 3411 and is provided with an insertion hole 3413 at one end of the socket 3411; and a light guiding strip 3414, which is inserted into the insertion holes 3413 of the sockets 3411 respectively at two ends of the light guiding strip, and the light guiding strip 3414 is peripherally disposed within the peripheral groove 322. Furthermore, the circuit board 34 includes an external connection port 342 and an internal connection port 343. The first housing 31 further includes a through hole 314 corresponding to the external connection port 342 so that the external connection port 342 passes through out of and is disposed within the through hole 314. The internal connection port 343 is electrically and signally connected to the hard disk drive 40.

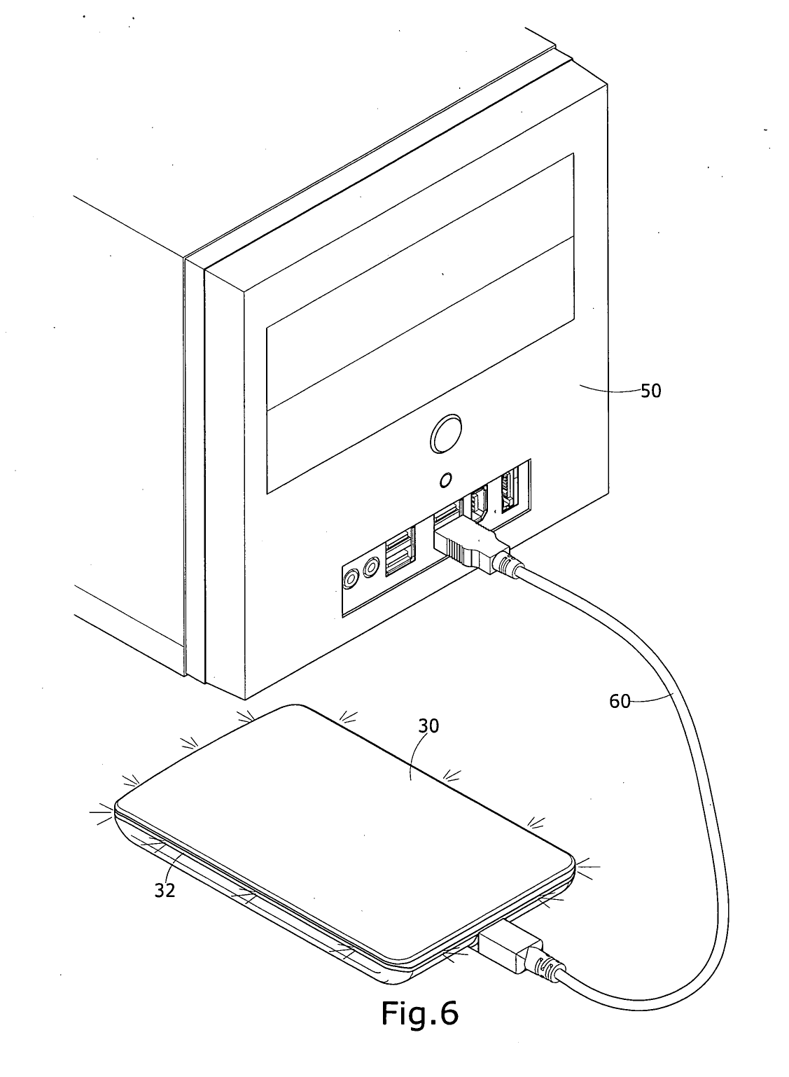

Referring to FIG. 6, there is shown a schematic view showing a state of a preferred embodiment according to the present invention when in use. Also, referring to FIG. 2, when the external hard disk drive case 30 of the present invention is connected to a computer device 50 in use, the case is electrically and signally connected to the computer device 50 at the external connection port 342 through a power signal line 60 whereby the computer device 50 can supply power to the circuit board 34 so that the luminous source 3412 is actuated and then lightened. The light emitted from the luminous source 3412 is guided into the light guiding strip 3414 to have an effect of lightening the whole strip. The light guiding strip 3414, which is located with respect to the light-transmitting trim ring 32, can produce a peripheral luminous effect for the external hard disk drive case 30 when in use, thus considerably improving the identifiable and aesthetic properties in use.

As described above and as shown in FIGS. 2 to 6, the present invention has the following advantages in practice:
1. After electrical and signal connection, the external hard disk drive case 30 of the present invention can produce a peripheral luminous effect through the trim ring 32 and light guiding strip 3414, thus considerably improving the identifiable and aesthetic properties in use.
2. Furthermore, according to the present invention, the first housing 31 and the second housing 33 can engage with each other by aligning and slidably inserting the hooks 331 provided on the second housing 33 into the snap-fitting portions 311 provided on the first housing 31, so as to enhance the convenience in assembly.
3. Moreover, the first positioning portions 323 provided on the trim ring 32 of the present invention engage with the second positioning portions 332 of the second housing 33 to increase the fixing effect after joined together.

What are described above are only preferred embodiments of the invention and should not be used to limit the scope of the present invention, and therefore all equivalent changes and modifications, such as the configuration and size of the first housing and second housing, the form and size of the trim ring, or the type of the luminous source, which do not depart from the spirit and scope of the present invention should be included in the appended claims.

In summarization of the foregoing description, the external hard disk drive case according to the present invention meets the requirements of inventiveness and industrial applicability of patents, and the application for a utility model patent is duly filed accordingly.

What is claimed is:

1. An external hard disk drive case for assembling a hard disk drive therein to serve as an external storage medium, comprising:
a first housing, provided with a plurality of snap-fitting portions extending inwardly on the periphery of the first housing, and a plurality of first fixed portions being provided between the snap-fitting portions and the inner wall surface of the first housing;
a trim ring, made of a light-transmitting material and with a shape corresponding to the first housing, the trim ring being provided with a plurality of second fixed portions corresponding to the first fixed portions, the second fixed portions and the first fixed portions of the first housing being joined to form one piece, a peripheral groove being formed between the trim ring and the snap-fitting portions of the first housing;
a second housing, provided with a plurality of hooks disposed on the surface of the second housing corresponding to the first housing, and the hooks engaging with the snap-fitting portions of the first housing; and
a circuit board, disposed within the first housing, the circuit board including a light-emitting component, the light-emitting component having:
at least one socket, provided with a luminous source disposed at the inner side of the socket, and an insertion hole being provided at one end of the socket; and
a light guiding strip, inserted into the insertion hole of the socket at one end of the light guiding strip, and the light guiding strip being peripherally disposed within the peripheral groove, and the luminous source lightening the whole light guiding strip after actuation, so as to light the periphery of the external hard disk drive case.

2. The external hard disk drive case as described in claim 1, wherein the snap-fitting portions respectively disposed on two sides of the first housing, and the first housing includes bulkheads on one side of the first housing, and the bulkheads are perpendicular to the inner surface of the first housing, so that the peripheral groove is formed between the bulkheads, the snap-fitting portions and the trim ring.

3. The external hard disk drive case as described in claim 1, wherein the trim ring further includes first positioning portions respectively on the upper edges of two sides of the trim ring, and the second housing further includes second positioning portions respectively corresponding to the first positioning portions, and the first positioning portions engage with the second positioning portions after the second housing is joined with the trim ring, so as to increase the fixing effect.

4. The external hard disk drive case as described in claim 1, wherein the circuit board is provided with two sockets, and two ends of the light guiding strip are respectively inserted into the sockets.

5. The external hard disk drive case as described in claim 1, wherein the circuit board further includes an external connection port, and the first housing further includes a through hole corresponding to the external connection port so that the external connection port passes through out of and is disposed within the through hole.

6. The external hard disk drive case as described in claim 1, wherein the circuit board further includes an internal connection port, and the internal connection port is electrically and signally connected to the hard disk drive.
